(19) United States
(12) Patent Application Publication
(10) Pub. No.: US 2025/0316613 A1
(43) Pub. Date: Oct. 9, 2025

(54) SEMICONDUCTOR DEVICE AND METHOD FOR MANUFACTURING OF SEMICONDUCTOR DEVICE

(71) Applicant: Mitsubishi Electric Corporation, Tokyo (JP)

(72) Inventors: Tetsunari SAITO, Tokyo (JP); Shunichi ABE, Tokyo (JP); Taketoshi MAEDA, Hyogo (JP)

(73) Assignee: Mitsubishi Electric Corporation, Tokyo (JP)

(21) Appl. No.: 18/865,931

(22) PCT Filed: Oct. 26, 2022
(86) PCT No.: PCT/JP2022/039983

§ 371 Date: Nov. 14, 2024

(51) Int. Cl. H01L 23/552; H01L 21/48; H01L 23/00; H01L 23/367

(52) U.S. Cl. CPC H01L 23/552; H01L 21/4853; H01L 21/4864; H01L 21/4882; H01L 23/3675; H01L 24/16; H01L 24/32; H01L 24/73; H01L 2224/16227; H01L 2224/32245; H01L 2224/73253; H01L 2924/16151; H01L 2924/16235; H01L 2924/16251; H01L 2924/3025; H01L 2924/37001

(57) ABSTRACT

A semiconductor chip (2) is flip-chip mounted on a substrate (1). A metal lid (4) is bonded on the substrate (1) so as to cover the semiconductor chip (2) and includes a top panel having an opening (6) formed above the semiconductor chip (2). A metal joint material (7) bonds the top panel of the metal lid (4) and a back electrode (8) of the semiconductor chip (2) to close the opening (6).

### FIELD

The present disclosure relates to a semiconductor device and a method for manufacturing the semiconductor device.

### BACKGROUND

A semiconductor device having a back surface cooling structure and electromagnetic shielding performance has been proposed. In the semiconductor device in related art, a heatsink is die-bonded on a back surface of an MMIC that is flip-chip mounted on a package substrate. The heatsink is exposed from a back surface of the package by back grinding after resin sealing. Heat of the MMIC is dissipated to a heat dissipation mechanism such as a module via the heatsink. An outer surface of the resin is covered by a metal shield film and has shielding property with respect to disturbance (see, for example, PTL 1).

### CITATION LIST

### Patent Literature

[PTL 1] JP 7031004 B

### SUMMARY OF THE INVENTION

### Problem to be Solved by the Invention

In the semiconductor device in the related art, it is necessary to die-bond the heatsink on the back surface of the MMIC. Further, a special step such as back grinding and formation of a shield film is required. Thus, there is a problem that manufacturing cost increases, and a manufacturing period becomes longer.

The present disclosure has been made to solve the problem as described above, and an object of the present disclosure is to provide a semiconductor device that can achieve reduction of manufacturing cost and shortening of a manufacturing period without impairing a back surface cooling structure and electromagnetic shielding performance, and a method for manufacturing the semiconductor device.

### Solution to Problem

A semiconductor device according to the present disclosure includes: a substrate; a semiconductor chip flip-chip mounted on the substrate; a metal lid bonded on the substrate so as to cover the semiconductor chip and including a top panel having an opening formed above the semiconductor chip; and a metal joint material bonding the top panel of the metal lid and a back electrode of the semiconductor chip to close the opening.

A method for manufacturing a semiconductor device according to the present disclosure includes: flip-chip mounting a semiconductor chip on a substrate; placing an opening formed on a top panel of a metal lid above the semiconductor chip and bonding the metal lid to the substrate so as to cover the semiconductor chip; and injecting a metal joint material into the opening, melting the metal joint material to bond the top panel of the metal lid and a back electrode of the semiconductor chip, and closing the opening with the metal joint material.

### Advantageous Effects of Invention

In the present disclosure, heat can be dissipated from the back surface of the package via the solder material and the metal lid. Electromagnetic shielding performance can be secured by the metal lid, and thus, it is not necessary to form a shield film on an outer surface of the package. Further, resin sealing is not required, and thus, back grinding of the resin is also not required. It is therefore possible to reduce manufacturing cost and shorten a manufacturing period without impairing a back surface cooling structure and electromagnetic shielding performance.

### BRIEF DESCRIPTION OF THE DRAWINGS

FIG. 1 is a cross-sectional view illustrating a semiconductor device according to Embodiment 1.

FIG. 2 is a plan view illustrating inside of the semiconductor device according to Embodiment 1.

FIG. 3 is a flowchart of a manufacturing step of the semiconductor device according to Embodiment 1.

FIG. 4 is a cross-sectional view illustrating the manufacturing step of the semiconductor device according to Embodiment 1.

FIG. 5 is a cross-sectional view illustrating a semiconductor device according to Embodiment 2.

FIG. 6 is a cross-sectional view illustrating a manufacturing step of the semiconductor device according to Embodiment 2.

FIG. 7 is a cross-sectional view illustrating a semiconductor device according to Embodiment 3.

FIG. 8 is a cross-sectional view illustrating a manufacturing step of the semiconductor device according to Embodiment 3.

FIG. 9 is a cross-sectional view illustrating a semiconductor device according to Embodiment 4.

FIG. 10 is a cross-sectional view illustrating a semiconductor device according to Embodiment 5.

FIG. 11 is a cross-sectional view illustrating a semiconductor device according to the comparative example.

FIG. 12 is a cross-sectional view illustrating a semiconductor device according to Embodiment 6.

FIG. 13 is a plan view illustrating a back surface of a semiconductor chip according to Embodiment 6.

FIG. 14 is a cross-sectional view illustrating a semiconductor device according to Embodiment 7.

FIG. 15 is a cross-sectional view illustrating a manufacturing step of a semiconductor device according to Embodiment 8.

FIG. 16 is a cross-sectional view illustrating a semiconductor device according to Embodiment 9.

### DESCRIPTION OF EMBODIMENTS

A semiconductor device and a method for manufacturing the semiconductor device according to the embodiments of the present disclosure will be described with reference to the drawings. The same components will be denoted by the same symbols, and the repeated description thereof may be omitted.

### Embodiment 1

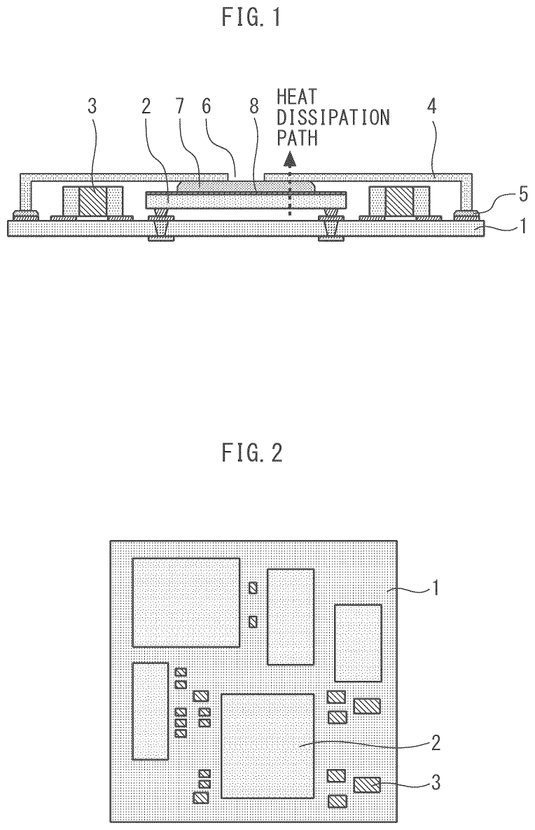

FIG. 1 is a cross-sectional view illustrating a semiconductor device according to Embodiment 1. FIG. 2 is a plan view illustrating inside of the semiconductor device according to Embodiment 1. This semiconductor device is a high-frequency semiconductor device having a back surface cooling structure and electromagnetic shielding performance.

A plurality of semiconductor chips 2 are flip-chip mounted on an upper surface of a multilayer organic substrate 1. Surface electrodes of the semiconductor chips 2 are soldered on an upper electrode of the multilayer organic substrate 1. Surface-mounted components 3 such as capacitors are also mounted on the upper surface of the multilayer organic substrate 1. A metal lid 4 is bonded on the upper surface of the multilayer organic substrate 1 with solder 5 so as to cover the semiconductor chips 2 and the surface-mounted components 3. An opening 6 is formed on a top panel of the metal lid 4 above a central portion of the semiconductor chip 2. A solder material 7 bonds a lower surface of the top panel of the metal lid 4 and a back electrode 8 of the semiconductor chip 2, thereby closing the opening 6. The metal lid 4 is connected to a GND of the multilayer organic substrate 1.

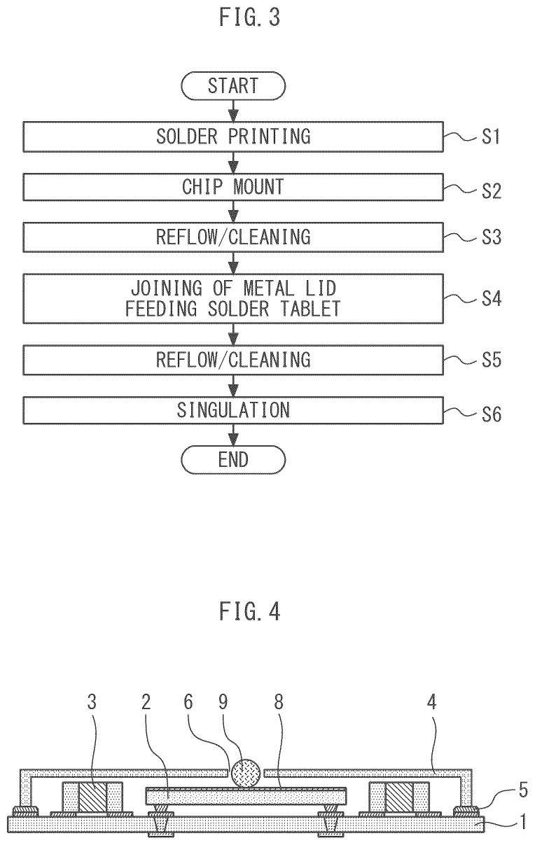

Subsequently, a method for manufacturing the above-described semiconductor device will be described. FIG. 3 is a flowchart of a manufacturing step of the semiconductor device according to Embodiment 1. FIG. 4 is a cross-sectional view illustrating the manufacturing step of the semiconductor device according to Embodiment 1.

First, solder paste is printed on the upper surface of the multilayer organic substrate 1 (step S1). The semiconductor chip 2 and the surface-mounted component 3 are mounted on the solder paste (step S2). The solder paste is melted by reflow to flip-chip mount the semiconductor chip 2 on the multilayer organic substrate 1 (step S3). The surface-mounted component 3 is also mounted on the multilayer organic substrate 1. After the reflow, the multilayer organic substrate 1 is cleaned.

Then, the metal lid 4 is bonded to the multilayer organic substrate 1 so as to cover the semiconductor chip 2 while the opening 6 formed on the top panel of the metal lid 4 is placed above the semiconductor chip 2. Then, a solder tablet 9 is injected into the opening 6 (step S4). A solder ball may be used instead of the solder tablet 9. The solder tablet 9 is melted by reflow to bond the top panel of the metal lid 4 and the back electrode 8 of the semiconductor chip 2, thereby closing the opening 6 (step S5). The solder tablet 9 after the reflow is the solder material 7. The multilayer organic substrate 1 is cleaned after the reflow. Finally, a wafer is singulated (step S6).

As described above, in the present embodiment, heat of the semiconductor chip 2 can be dissipated from the back surface of the package via the solder material 7 and the metal lid 4. Electromagnetic shielding performance with respect to disturbance can be secured by the metal lid 4, and thus, it is not necessary to form a shield film on an outer surface of the package. Further, resin sealing is not required, and thus, back grinding of the resin is also not required. It is therefore possible to reduce manufacturing cost and shorten a manufacturing period without impairing a back surface cooling structure and electromagnetic shielding performance. Further, a heatsink for each chip is not required, and thus, further reduction in height can be achieved.

Further, the opening 6 is formed on the top panel of the metal lid 4 above a central portion of each of the plurality of semiconductor chips 2. The solder tablet 9 is injected into each opening 6, and reflow is performed. Each solder material 7 bonds the top panel of the metal lid 4 and the back electrode 8 of each chip, thereby closing the opening 6 above each chip. Variation in height after the plurality of semiconductor chips 2 are mounted is absorbed by the solder material 7 on the back surfaces of the chips, and thus, the plurality of semiconductor chips 2 can be mounted on the same package. Further, an amount of the solder material 7 to be injected is adjusted in anticipation of a worst value of tolerance, and excessive solder is let out from the opening 6. This can improve a manufacturing yield.

Note that while in the present embodiment, the solder material 7 is used as a metal joint material that bonds the metal lid 4 and the semiconductor chip 2 to close the opening 6, the metal joint material is not limited to this, and a metal joint material having favorable thermal conductivity and favorable electric conductivity can be used.

### Embodiment 2

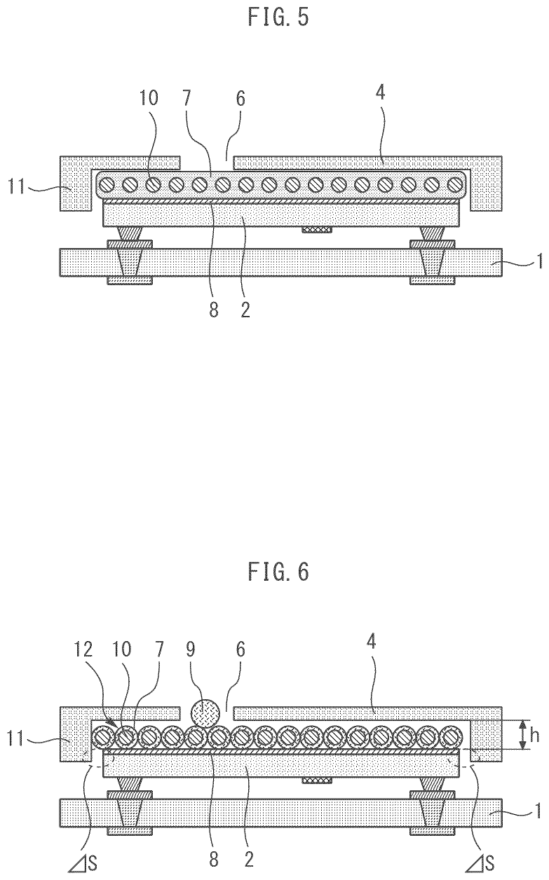

FIG. 5 is a cross-sectional view illustrating a semiconductor device according to Embodiment 2. In the present embodiment, as a metal joint material that bonds the metal lid 4 and the back surface of the semiconductor chip 2 to close the opening 6, a mixture of the solder material 7 and a metal ball 10 formed with Cu is used. Thermal conductivity of the solder material 7 is about 30 to 60 W/m·K depending on a type and a ratio of an alloy. Thermal conductivity of Cu is 398 W/m·K. In other words, thermal conductivity of the metal ball 10 is higher than the thermal conductivity of the solder material 7. Thus, the present embodiment excels in heat dissipation compared to Embodiment 1 in which a space between the back surface of the semiconductor chip 2 and the metal lid 4 is filled only with the solder material 7. Further, most portion of the space is occupied by the metal ball 10, and thus, a large void that affects thermal resistance is less likely to occur. Note that a material of the metal ball 10 is not limited to Cu if the material is a metal having higher thermal conductivity than the thermal conductivity of the solder material 7, and may be, for example, Ag. However, Au is expensive, and Al is hard to use.

A projection 11 extending to a side of each semiconductor chip 2 is provided on a lower surface of the top panel of the metal lid 4. For example, a diameter of the metal ball 10 is set at 300 μm, a height h of the projection 11 is set at 350 μm, and an interval As in a lateral direction between a side surface of the semiconductor chip 2 and a side surface of the projection 11 is set at 140 μm. By making the interval As smaller than the diameter of the metal ball 10, it is possible to prevent the metal ball 10 from dropping from the back surface of the semiconductor chip 2.

FIG. 6 is a cross-sectional view illustrating a manufacturing step of the semiconductor device according to Embodiment 2. A Cu core ball 12 is injected into the opening 6 to fill a space between the metal lid 4 and the back surface of the semiconductor chip 2. The Cu core ball 12 is obtained by covering a surface of the metal ball 10 formed with Cu with the solder material 7. The solder material 7 of the Cu core ball 12 is melted by reflow, and the metal lid 4 and the back surface of the semiconductor chip 2 are soldered. The space between the metal lid 4 and the semiconductor chip 2 cannot be filled only with the solder material 7 of the Cu core ball 12, and thus, after the Cu core ball 12 is injected into the opening 6, the solder tablet 9 is further injected into the opening 6. A width of the opening 6 of the metal lid 4 is designed larger by, for example, 50% than outer shapes of the Cu core ball 12 and the solder tablet 9. Other configurations and effects are similar to those in Embodiment 1.

### Embodiment 3

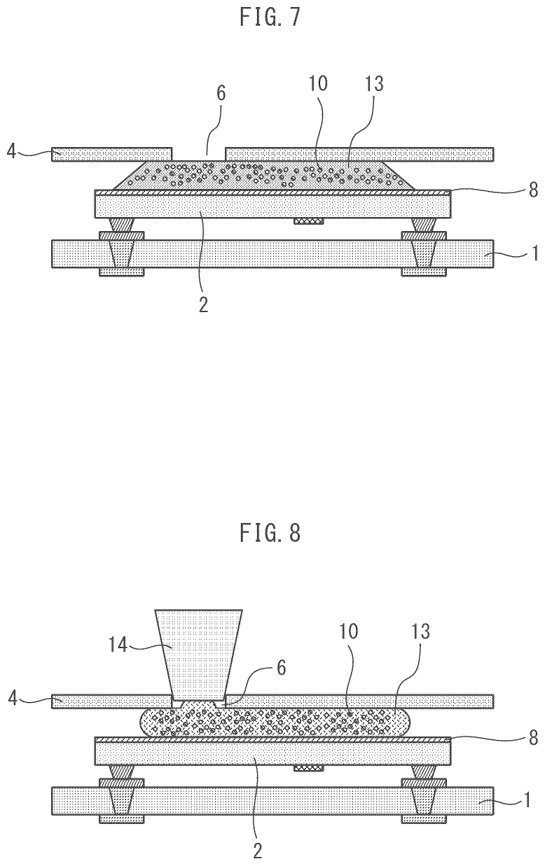

FIG. 7 is a cross-sectional view illustrating a semiconductor device according to Embodiment 3. As the metal joint material, solder paste 13 in which the metal ball 10 formed with Cu is mixed is used. Note that as the metal joint material, resin paste in which an Ag filler is mixed or Ag nanoparticles can be used. However, solder has higher thermal conductivity than thermal conductivity of the resin paste in which the Ag filler is mixed.

FIG. 8 is a cross-sectional view illustrating a manufacturing step of the semiconductor device according to Embodiment 3. The solder paste 13 is injected into the opening 6 of the metal lid 4 from a nozzle 14 of a dispense that is a solder coating device. The solder paste 13 has high viscosity, and thus, the metal ball 10 does not roll and drop from the back surface of the chip. A radius of the metal ball 10 is smaller than a radius of the Cu core ball 12 in FIG. 6 and does not affect variation in height. Other configurations and effects are similar to those in Embodiment 2.

### Embodiment 4

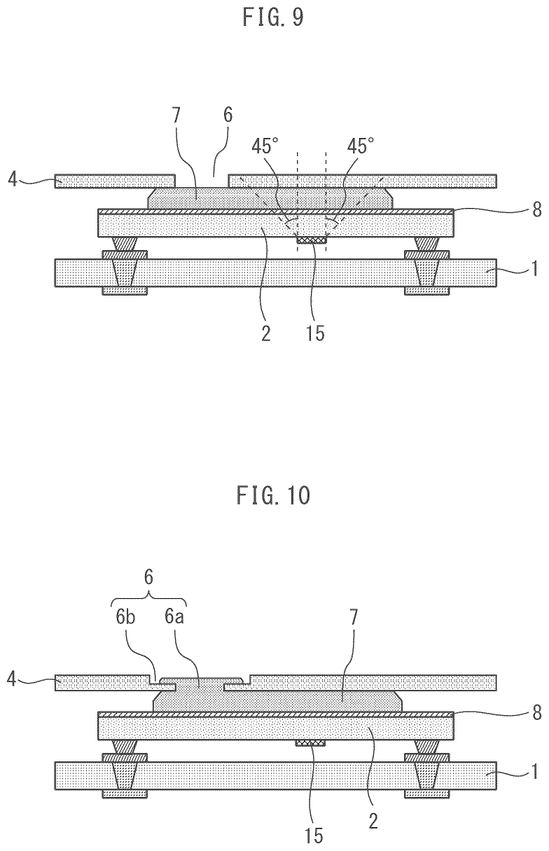

FIG. 9 is a cross-sectional view illustrating a semiconductor device according to Embodiment 4. A heat generation portion 15 such as a transistor is formed on a surface of the semiconductor chip 2. Heat typically diffuses at a gradient of 45 degrees with respect to a heat generation surface. Thus, the opening 6 with low thermal conductivity is prevented from being formed within a thermal diffusion region of 45 degrees from the heat generation portion 15 toward the top panel of the metal lid 4. This prevents the opening 6 from interfering with thermal diffusion from the heat generation portion 15, so that thermal resistance of a device can be reduced. Other configurations and effects are similar to those in Embodiment 1, and the like.

### Embodiment 5

FIG. 10 is a cross-sectional view illustrating a semiconductor device according to Embodiment 5. The opening 6 includes a first opening 6a, and a second opening 6b formed above the first opening 6a and having a width wider than a width of the first opening 6a.

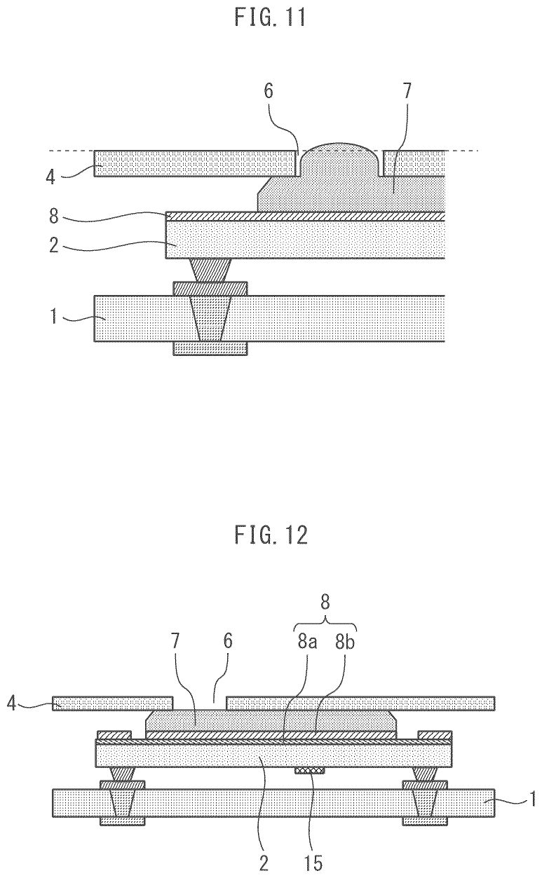

Effects of the present embodiment will be described in comparison to a comparative example. FIG. 11 is a cross-sectional view illustrating a semiconductor device according to the comparative example. In the comparative example, a width of the opening 6 is uniform. For example, in a case where an interval between the metal lid 4 and the semiconductor chip 2 becomes small by variation in height of the semiconductor chip 2, an extra solder material 7 spills over the top panel of the metal lid 4 from the opening 6 after the reflow. This results in making it impossible to achieve flatness of the top panel of the metal lid 4 and making it difficult to press a surface of the top panel against a radiating fin, and the like.

In contrast, in the present embodiment, even in a case where a solder amount is excessive, the extra solder material 7 flows into the second opening 6b with a wider width. It is therefore possible to prevent occurrence of elevation of the solder material 7 that might spill over the top panel of the metal lid 4. Other configurations and effects are similar to those in Embodiment 1, and the like.

### Embodiment 6

FIG. 12 is a cross-sectional view illustrating a semiconductor device according to Embodiment 6. The back electrode 8 includes first metal plating 8a and second metal plating 8b formed on the first metal plating 8a. The first metal plating 8a is a metal with poor solder wettability and is, for example, Ni. The second metal plating 8b is a metal with good solder wettability and is, for example, Au. In other words, the second metal plating 8b has better wettability of the solder material 7 than the first metal plating 8a.

FIG. 13 is a plan view illustrating a back surface of a semiconductor chip according to Embodiment 6. In a jointed region in which the opening 6 and the heat generation portion 15 are located in a planar view, the second metal plating 8b is formed, and the first metal plating 8a is not exposed. In an exposure region surrounding the jointed region in a planar view, an opening is formed in the second metal plating 8b, and the first metal plating 8a is exposed from the second metal plating 8b. In a peripheral region of the semiconductor chip 2 outside the exposure region, the second metal plating 8b is formed, and the first metal plating 8a is not exposed.

The first metal plating 8a with poor wettability is circularly exposed so as to surround a circumference of the opening 6 and the heat generation portion 15 in a planar view. The solder material 7 bonds the second metal plating 8b and the metal lid 4 in the jointed region and does not leak out to the exposure region in which the first metal plating 8a with poor wettability is exposed. It is therefore possible to reduce defects such as solder leakage to an unnecessary region and crawling out of solder from the back surface of the chip. Other configurations and effects are similar to those in Embodiment 1, and the like.

### Embodiment 7

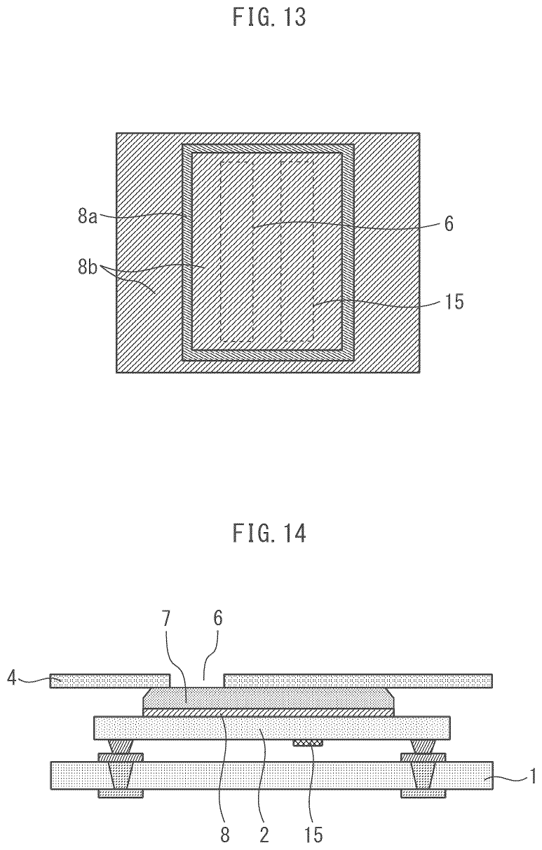

FIG. 14 is a cross-sectional view illustrating a semiconductor device according to Embodiment 7. The back electrode 8 is formed at the central portion of the back surface of the semiconductor chip 2, and a semiconductor of the semiconductor chip 2 is exposed at a peripheral portion on the back surface of the semiconductor chip 2. GaAs and SiC have poor metal wettability, and Si also has poor wettability depending on metals. It is therefore possible to reduce defects such as solder leakage to an unnecessary region and crawling out of solder from the back surface of the chip. Other configurations and effects are similar to those in Embodiment 1, and the like.

### Embodiment 8

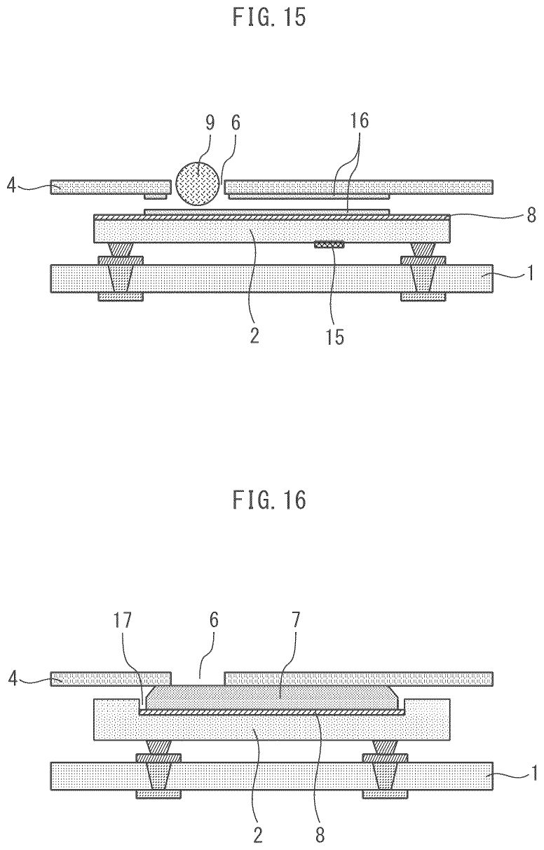

FIG. 15 is a cross-sectional view illustrating a manufacturing step of a semiconductor device according to Embodiment 8. Metal plating 16 having better wettability of the solder material 7 than the back electrode 8 and the metal lid 4 is formed on a lower surface of the metal lid 4 and the back electrode 8. The metal plating 16 is the same material as the material of the solder material 7 and is, for example, Sn—Ag—Cu based medium-temperature solder.

In a case where the heat generation portion 15 is separate from the opening 6 of the metal lid 4, even if the solder material 7 is injected from the opening 6, there is a possibility that a portion above the heat generation portion 15 may not get wet with the solder material 7. Thus, in the present embodiment, the metal plating 16 is applied in advance in a region desired to be filled with the solder material 7. This makes it easier for the solder material 7 to flow deeply upon reflow, so that it is possible to reduce thermal resistance. Other configurations and effects are similar to those in Embodiment 1, and the like.

### Embodiment 9

FIG. 16 is a cross-sectional view illustrating a semiconductor device according to Embodiment 9. A recess 17 is formed at the central portion on the back surface of the semiconductor chip 2. The back electrode 8 is formed on a bottom surface of the recess 17. The back electrode 8 is not formed at a peripheral portion on the back surface of the semiconductor chip 2, and the semiconductor is exposed.

The peripheral portion on the back surface of the semiconductor chip 2 projects compared to the central portion, does not have the back electrode 8 and has poor solder wettability. Thus, even in a case where a solder amount is excessive, it is possible to prevent the solder material 7 from spilling over the peripheral portion on the back surface and leaking out to the side surface of the chip. Oher configurations and effects are similar to those in Embodiment 1, and the like.

### REFERENCE SIGNS LIST

1 multilayer organic substrate (substrate); 2 semiconductor chip; 4 metal lid; 6 opening; 6a first opening; 6b second opening; 7 solder material (metal joint material); 8 back electrode; 8a first metal plating; 8b second metal plating; 9 solder tablet (metal joint material); 10 metal ball (metal joint material); 11 projection; 13 solder paste (metal joint material); 15 heat generation portion; 16 metal plating; 17 recess

1. A semiconductor device comprising:
a substrate;
a semiconductor chip flip-chip mounted on the substrate;
a metal lid bonded on the substrate so as to cover the semiconductor chip and including a top panel having an opening formed above the semiconductor chip; and
a metal joint material bonding the top panel of the metal lid and a back electrode of the semiconductor chip to close the opening,
wherein the metal joint material is a mixture of a solder material and a metal ball having higher thermal conductivity than thermal conductivity of the solder material,
a projection extending to a side of the semiconductor chip is provided on a lower surface of the top panel of the metal lid, and
an interval between a side surface of the semiconductor chip and a side surface of the projection is smaller than a diameter of the metal ball.

2. The semiconductor device according to claim 1, wherein the semiconductor chip includes a plurality of chips,
the opening is formed on the top panel of the metal lid above each chip, and
the metal joint material bonds the top panel of the metal lid and the back electrode of each chip and closes the opening above each chip.

3.-4. (canceled)

5. A semiconductor device comprising:
a substrate;
a semiconductor chip flip-chip mounted on the substrate;
a metal lid bonded on the substrate so as to cover the miconductor chip and including a top panel having an opening formed above the semiconductor chip; and
a metal joint material bonding the top panel of the metal lid and a back electrode of the semiconductor chip to close the opening,
wherein a heat generation portion is formed on a surface of the semiconductor chip, and
the opening is not formed within a thermal diffusion region of 45 degrees from the heat generation portion toward the top panel of the metal lid.

6. A semiconductor device comprising:
a substrate;
a semiconductor chip flip-chip mounted on the substrate;
a metal lid bonded on the substrate so as to cover the semiconductor chip and including a top panel having an opening formed above the semiconductor chip; and
a metal joint material bonding the top panel of the metal lid and a back electrode of the semiconductor chip to close the opening,
wherein the opening includes a first opening, and a second opening formed above the first opening and having a width wider than a width of the first opening.

7. The semiconductor device according to claim 5, wherein the back electrode includes first metal plating, and second metal plating formed on the first metal plating and having better wettability of the metal joint material than the first metal plating,
the second metal plating is formed in a jointed region in which the opening and the heat generation portion are located in a planar view, and
the first metal plating is exposed from the second metal plating in an exposure region surrounding the jointed region in a planar view.

8. The semiconductor device according to claim 1, wherein the back electrode is formed at a central portion of a back surface of the semiconductor chip, and a semiconductor of the semiconductor chip is exposed at a peripheral portion on the back surface of the semiconductor chip.

9. The semiconductor device according to claim 1, wherein metal plating having better wettability of the metal joint material than the back electrode and the metal lid is formed on a lower surface of the metal lid and the back electrode.

10. The semiconductor device according to claim 1, wherein a recess is formed at a central portion on a back surface of the semiconductor chip, and
the back electrode is formed on a bottom surface of the recess and is not formed at a peripheral portion on the back surface of the semiconductor chip.

11.-13. (canceled)

14. The semiconductor device according to claim 5, wherein the semiconductor chip includes a plurality of chips,
the opening is formed on the top panel of the metal lid above each chip, and
the metal joint material bonds the top panel of the metal lid and the back electrode of each chip and closes the opening above each chip.

15. The semiconductor device according to claim 6, wherein the semiconductor chip includes a plurality of chips,
the opening is formed on the top panel of the metal lid above each chip, and
the metal joint material bonds the top panel of the metal lid and the back electrode of each chip and closes the opening above each chip.

16. The semiconductor device according to claim 5, wherein the metal joint material is a mixture of a solder material and a metal ball having higher thermal conductivity than thermal conductivity of the solder material.

17. The semiconductor device according to claim 6, wherein the metal joint material is a mixture of a solder material and a metal ball having higher thermal conductivity than thermal conductivity of the solder material.

18. The semiconductor device according to claim 5, wherein metal plating having better wettability of the metal joint material than the back electrode and the metal lid is formed on a lower surface of the metal lid and the back electrode.

19. The semiconductor device according to claim 6, wherein metal plating having better wettability of the metal joint material than the back electrode and the metal lid is formed on a lower surface of the metal lid and the back electrode.

20. The semiconductor device according to claim 8, wherein metal plating having better wettability of the metal joint material than the back electrode and the metal lid is formed on a lower surface of the metal lid and the back electrode.
